(19) United States
(12) Patent Application Publication
(10) Pub. No.: US 2003/0057438 A1
(43) Pub. Date: Mar. 27, 2003

(54) Structure and method for fabricating semiconductor structures and devices utilizing lateral epitaxial overgrowth

(75) Inventors: Zhiyi Yu, Gilbert, AZ (US); Ravindranath Droopad, Chandler, AZ (US); Dirk C. Jordan, Gilbert, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: MOTOROLA, INC., Schaumburg, IL (US)

(21) Appl. No.: 09/960,402

(22) Filed: Sep. 24, 2001

(51) Int. Cl. H01L 29/76; H01L 29/04

(52) U.S. Cl. 257/190

(57) ABSTRACT

High quality epitaxial layers of monocrystalline materials can be grown overlying monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. In addition, formation of a compliant substrate may include the use lateral epitaxial overgrowth to facilitate production of a high quality monocrystalline material layer.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that utilize lateral epitaxial overgrowth processing to form a high quality monocrystalline material layer on a substrate.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention; and

FIGS. 24-29 illustrate schematically, in cross-section, device structures in accordance with other embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIB and VB elements (III-V semiconductor compounds), mixed III-V compounds, Group II(A or B) and VIA elements (II-VI semiconductor compounds), mixed II-VI compounds, Group IV and VI elements (IV-VI semiconductor compounds), and mixed IV-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

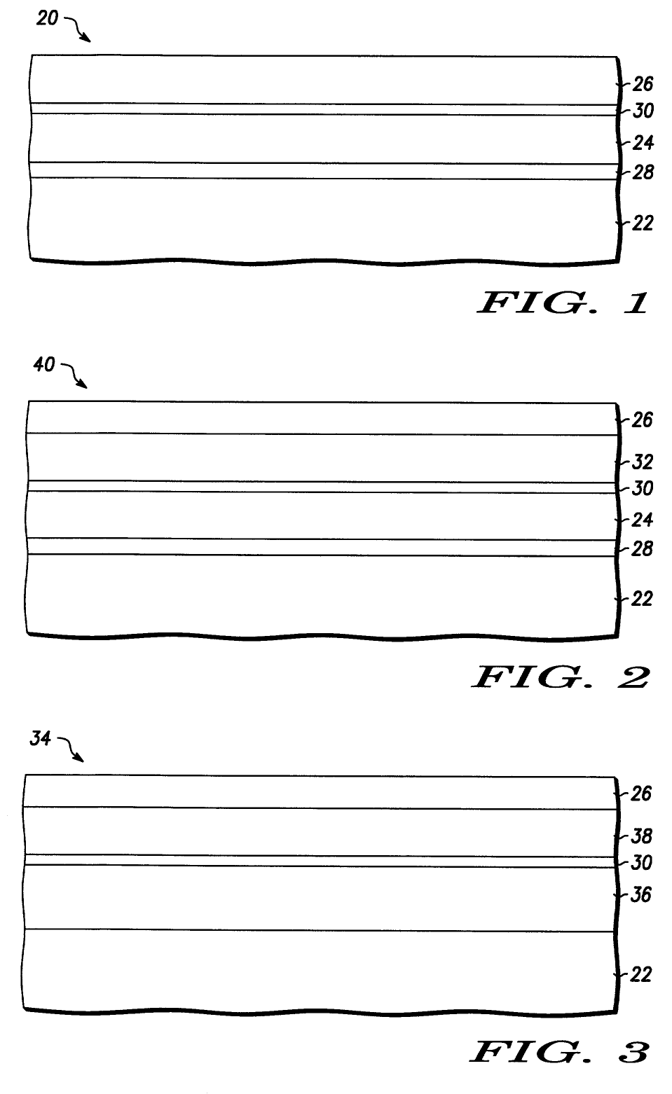

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous interface layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous interface layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Ti—O—As, Ti—Ga, Ti—O—Ga, Sr—O—As, Sr—Ga—O, or Sr—Al—O. By way of a preferred example, 1-2 monolayers of Ti—O—As or Ti—O—Ga have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSSe.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z} TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

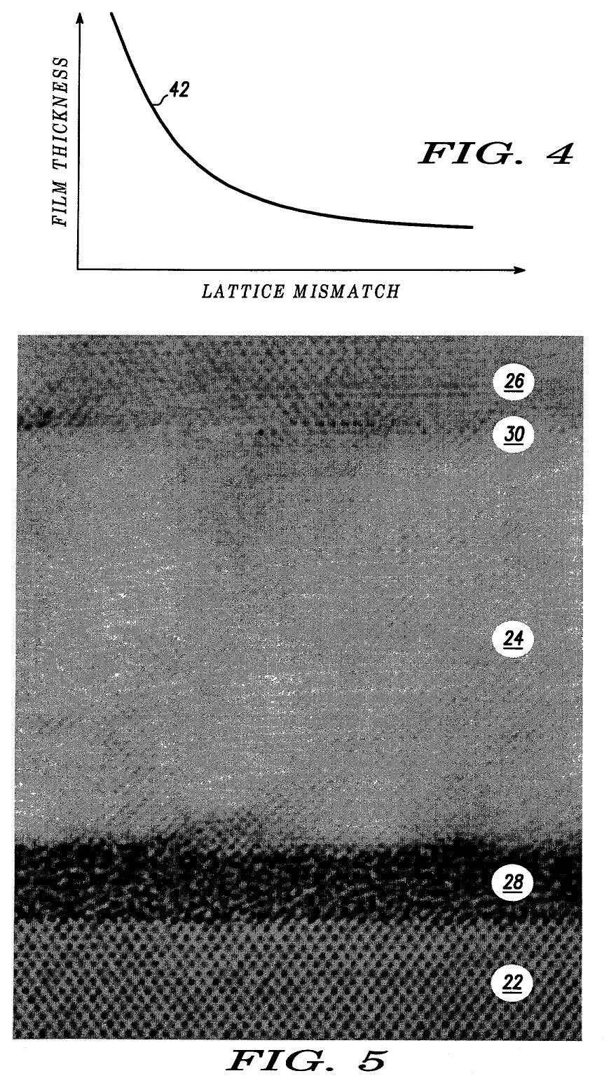

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin high quality silicon oxide protective layer may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 725° C. to about 800° C. to cause the strontium to react with the native silicon oxide layer. The strontium serves to reduce the silicon oxide to leave a silicon oxide-free surface. The resultant surface may exhibit an ordered (2×1) structure. If an ordered (2×1) structure has not been achieved at this stage of the process, the structure may be exposed to additional strontium until an ordered (2×1) structure is obtained. The ordered (2×1) structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 725° C. to about 800° C. At this temperature a solid state reaction takes place between the strontium oxide and the native silicon oxide causing the reduction of the native silicon oxide and leaving an ordered (2×1) structure on the substrate surface. If an ordered (2×1) structure has not been achieved at this stage of the process, the structure may be exposed to additional strontium until an ordered (2×1) structure is obtained. Again, this forms a template for the subsequent growth of an ordered monocrystalline oxide layer.

In accordance with another alternate embodiment of the invention, the native oxide may be removed by depositing Si, Ge, or the combination of Si and Ge by MBE at temperatures ranging from about 200° C. to about 900° C., and perferably from about 750° C. to about 830° C., in ultrahigh vacuum. Again, an orderd template may then be formed on the substrate surface by depositing alkaline earth metals such as Sr, Ba or a combination of Sr and Ba.

Following the removal of the silicon oxide from the surface of the substrate and the formation of the above-described template, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.1-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the strontium titanate layer during the strontium titanate layer growth or a post-growth anneal in an oxygen environment. The growth of the silicon oxide layer results from the diffusion of oxygen through the strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Ti—Ga bond, a Ti—O—Ga bond, a Sr—Ga bond or a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

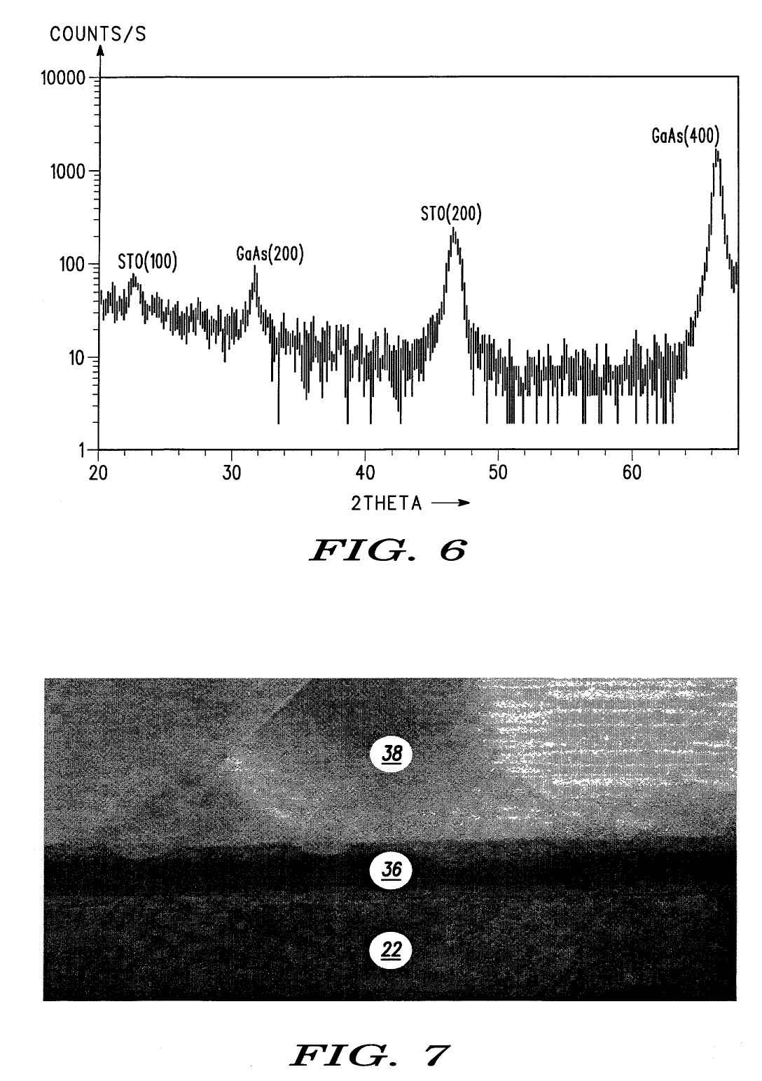

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

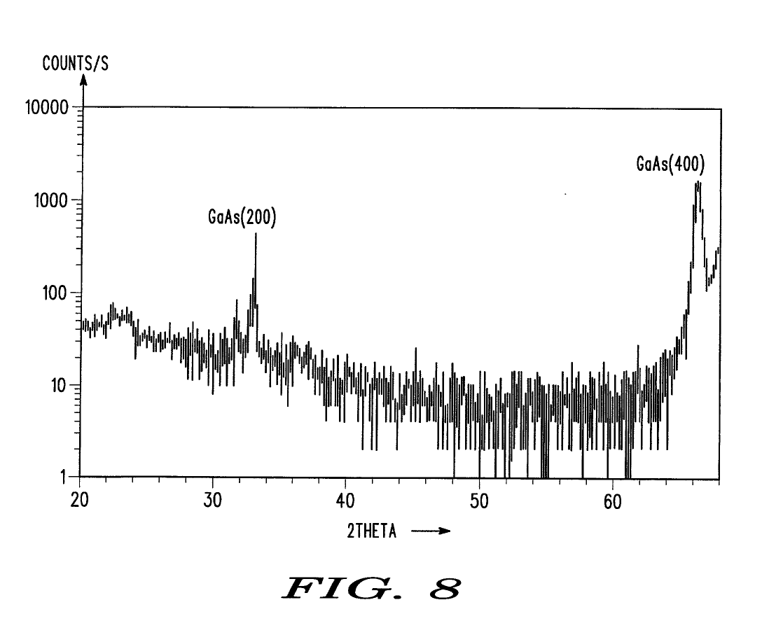

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

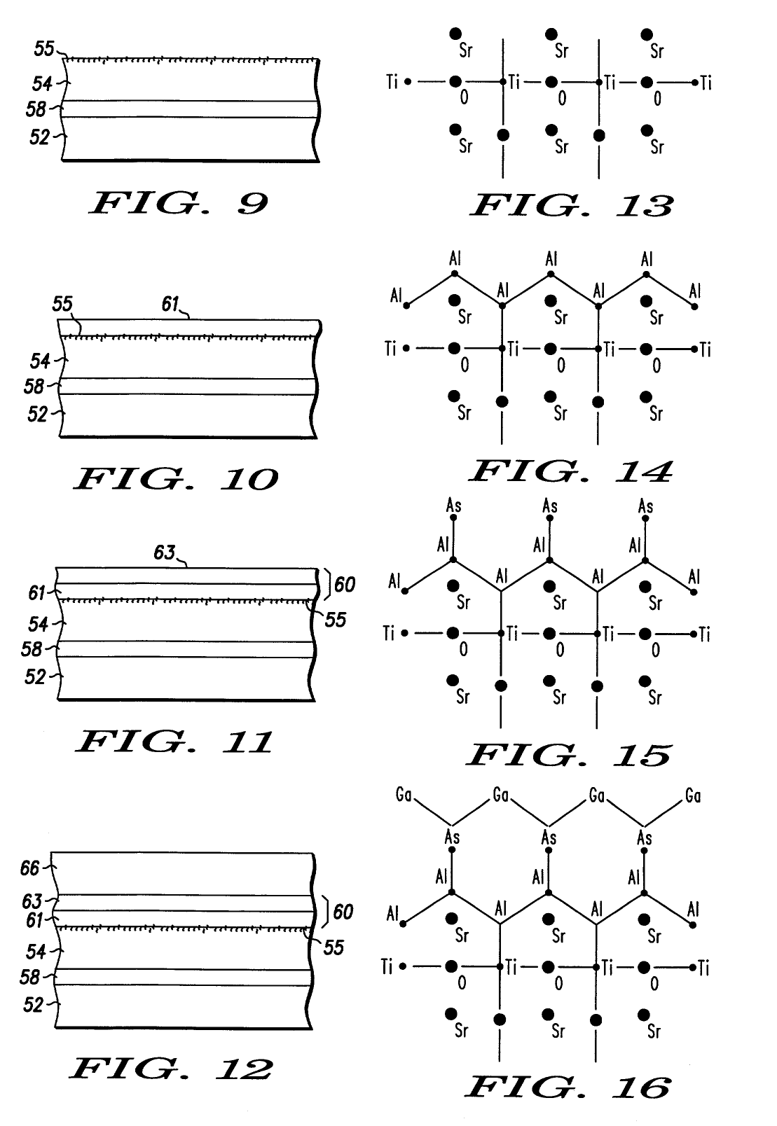

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Merve growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

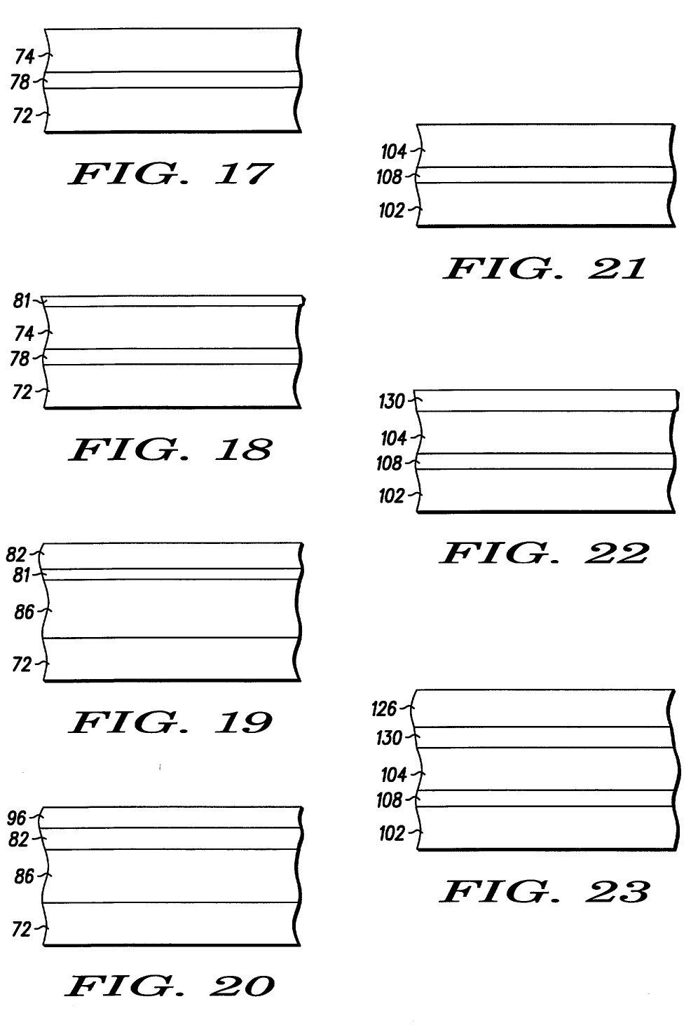

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zint1 type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zint1 type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

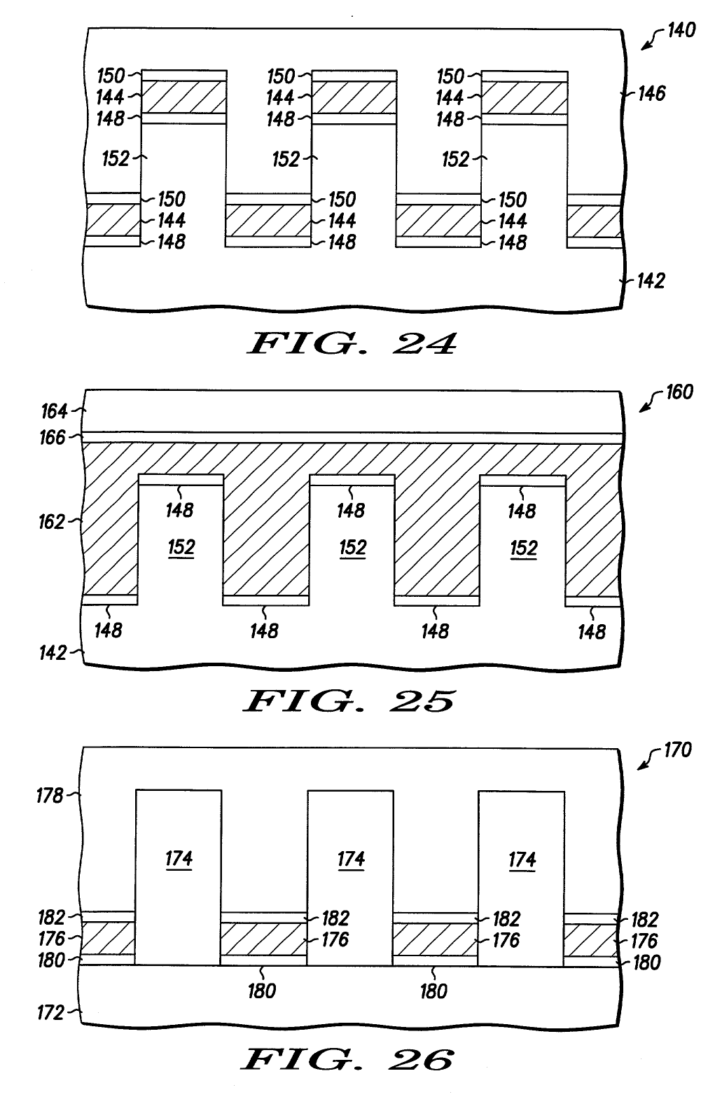

A monocrystalline material layer 126 is epitaxially grown over template layer 130 to achieve the final structure illustrated in FIG. 23. As a specific example, an SrAl₂ layer maybe used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zint1 phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zint1 type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

A portion of a semiconductor structure 140 formed in accordance with another embodiment of the invention utilizing lateral epitaxial overgrowth processing is illustrated in FIG. 24. Like the previously described embodiments referred to in FIGS. 1-3, this embodiment of the invention involves the process of forming a compliant substrate for the epitaxial growth of single crystal materials.

Semiconductor structure 140 includes a monocrystalline silicon substrate 142 having formed integrally on its surface a plurality of patterned features 152, a discontinuous accommodating buffer layer 144, and a monocrystalline material layer 146. In accordance with one embodiment of the invention, structure 140 also includes a discontinuous amorphous interface layer 148 positioned between substrate 142 and monocrystalline accommodating buffer layer 144. Amorphous interface layer 148 may be formed of a silicon oxide such as that comprising layer 28 of FIGS. 1 and 2. Structure 140 may also include a discontinuous template layer 150 between accommodating buffer layer 144 and monocrystalline material layer 146. Template layer 150 may be formed of any of the materials that comprise template layer 30 of FIGS. 1-3, template layer 60 of FIG. 12, capping layer 82 of FIG. 20 and template layer 130 of FIG. 23.

Patterned features 152 are formed from the top surface of monocrystalline substrate 142. Patterned features 152 maybe formed at the surface of substrate 142 by any suitable method, such as reactive ion etching, photolithography, sputtering, hydroflouric acid etching, micromachining or a self-organized process. Patterned features 152 may be of any suitable size and shape that facilitates the subsequent lateral epitaxial overgrowth of a monocrystalline material between and over the patterned features. For example, patterned features 152 may have a square, circular, triangular, rectangular or any other suitable cross-sectional shape, or may be formed as concentric annular rings and the like, depending on a desired application. In addition, the patterned features may be undercut with the width of the top of the patterned features larger than the width of the bottom of the patterned features to further reduce the density of defects in the accommodating buffer layer. Typically, patterned features 152 have a width in the range of approximately 1-5000 μm, although preferably the width of the patterned features has a range of approximately 2-50 μm. The height of patterned features 152 is in the range of approximately 1 nm-10 μm, and preferably is in the range of approximately 10 nm-1 μm. The patterned features are typically spaced approximately 1-200 μm apart and are preferably 2-10 μm apart. It will be appreciated, however, that any suitable height, width and spacing that facilitates lateral epitaxial overgrowth of a material may be used.

A monocrystalline accommodating buffer layer material is deposited between and on patterned features 152 to form discontinuous accommodating buffer layer 144. Accommodating buffer layer 144 is preferably formed of an oxide that is closely lattice-matched to the monocrystalline material layer 146. Materials that are suitable for monocrystalline accommodating buffer layer 144 include those materials that comprise accommodating buffer layer 24 of FIGS. 1 and 2. Accommodating buffer layer 144 may be grown by the process described above for accommodating buffer layer 24 of FIGS. 1 and 2. In accordance with this embodiment, accommodating buffer layer 144 may have a thickness in the range of about 2 nm to about 100 nm and is preferably about 5 nm. By growing accommodating buffer layer 144 between and on patterned features 152, the lateral continuity of the accommodating buffer layer may be controlled, resulting in the reduction in defect density. Typically, when defects are present at the substrate/accommodating buffer layer interface, such as when caused by the lattice mismatch between the layers, the defects tend to propagate laterally before propagating vertically. Formation of the discontinuous accommodating buffer layer between patterned features 152 restricts the lateral propagation of the defects within the accommodating layer, thereby restricting the vertical propagation of the defects. Accordingly, the accommodating buffer layer grows vertically with a reduced number of defects compared to growth of the layer on substrate 142 without the use of patterned features 152.

Amorphous interface layer 148 is preferably an oxide formed by the oxidation of the surface of substrate 142, and more preferably is composed of a silicon oxide. The thickness of layer 148 is sufficient to relieve strain attributed to mismatches between the lattice constants of substrate 142 and accommodating buffer layer 144. Typically, layer 148 has a thickness in the range of approximately 0.5-5 nm, and, preferably, has a thickness in the range of approximately 1-2 nm.

Monocrystalline material layer 146 is grown via lateral epitaxial overgrowth (“LEO”) overlying accommodating buffer layer 24 and between patterned features 152. The monocrystalline material of layer 146 grows vertically to fill the space between patterned features 152 and then grows laterally over patterned features 152. With this growth process, defect density is reduced, as the lateral propagation of dislocations present at the accommodating buffer layer/monocrystalline material layer interface due to lattice mismatch are limited. Accordingly, the vertical propagation of the defects within the monocrystalline material layer is limited, thereby creating a high-quality, relatively defect-free monocrystalline material layer 146.

Monocrystalline material layer 146 may be grown to any suitable thickness, even beyond a “critical thickness.” Typically, when a second monocrystalline layer with a second crystalline structure is initially deposited on a first monocrystalline layer with a first crystalline structure, the second monocrystalline layer assumes the crystalline structure of the first monocrystalline layer and is, accordingly, strained. As the second monocrystalline layer grows in thickness, the second monocrystalline layer relaxes and dislocation defects begin to form to relieve the strain. The thickness at which the dislocation defects begin to form in the second monocrystalline layer is its “critical thickness.” When the lattice mismatch between the second monocrystalline layer and the first monocrystalline layer is large, the critical thickness of the second monocrystalline layer may be small as a high density of defects forms quickly at the interface. By using LEO processing, the vertical propagation of defects formed at the interface of the two monocrystalline layers due to lattice mismatch is controlled, and the second monocrystalline layer may be grown to any suitable thickness. Accordingly, by using LEO processing, the monocrystalline material layer 146 of structure 140 may be grown to any suitable thickness with a reduced number of defects as compared to a monocrystalline material layer formed without using LEO processing.

The material for monocrystalline material layer 146 can be selected, as desired, for a particular structure or application. For example, the monocrystalline material of layer 146 may comprise a compound semiconductor which can be selected, as needed for a particular semiconductor structure, from any of the Group “IIIA and VA elements (III-V semiconductor compounds), mixed III-V compounds, Group II(A or B) and VIA elements (II-VI semiconductor compounds), mixed II-VI compounds, Group IV and VI elements (IV-VI semiconductor compounds) and mixed IV-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe) and the like. However, monocrystalline material layer 146 may also comprise other semiconductor materials, metals, or non-metal materials that are used in the formation of semiconductor structures, devices and/or integrated circuits.

FIG. 25 illustrates, in cross section, a portion of a semiconductor structure 160 in accordance with a further embodiment of the invention. Structure 160 is similar to structure 140, as it comprises silicon substrate 142 with patterned features 152, as described above with reference to FIG. 24. Structure 160 further comprises an accommodating buffer layer 162. Accommodating buffer layer 162 may be formed of the same materials as set forth above and by the same process as for accommodating buffer layer 144 illustrated in FIG. 24. Accommodating buffer layer 162 is epitaxially grown overlying substrate 142 via LEO between and over patterned features 152. Accommodating buffer layer 162 grows vertically to fill the space between patterned features 152 and then grows laterally over patterned features 152. Using LEO processing, a high quality monocrystalline accommodating buffer layer may be grown to any suitable thickness over substrate 142.

In accordance with one embodiment of the invention, structure 160 also includes discontinuous amorphous interface layer 148 positioned between substrate 142 and monocrystalline accommodating buffer layer 162. A monocrystalline material layer 164 is epitaxially grown overlying accommodating buffer layer 162. Structure 160 may also include a template layer 166 formed between accommodating buffer layer 162 and monocrystalline material layer 164. Template layer 166 may be formed of any of the materials that comprise discontinuous template layer 150 of FIG. 24.

FIG. 26 illustrates, in cross section, a portion of a semiconductor structure 170 in accordance with a further embodiment of the invention. Semiconductor structure 170 includes a monocrystalline silicon substrate 172, a plurality of patterned features 174, a discontinuous accommodating buffer layer 176 and a monocrystalline material layer 178. Patterned features 174 are formed by lithographically depositing a dielectric material overlying substrate 172 for subsequent LEO processing. Patterned features 174 may be comprised of any suitable dielectric material but are preferably comprised of SiO₂ or SiNₓ, where x is greater than 0. As with patterned features 152 described with reference to FIGS. 24 and 25, patterned features 174 may be of any suitable size and shape that facilitate the subsequent lateral epitaxial overgrowth of a monocrystalline material between and over the patterned features. For example, patterned features 174 may have a square, circular, triangular, rectangular or any other suitable cross-sectional shape, or may be formed as concentric annular rings, or the like. In addition, the patterned features may be undercut with the width of the top of the patterned features larger than the width of the bottom of the patterned features. Typically, patterned features 174 have a width in the range of approximately 1-500 μm, although preferably the width of the patterned features has a range of approximately 2-50 μm. The height of patterned features 152 is in the range of approximately 1 nm-10 μm, and preferably is in the range of approximately 10 nm-1 μm. The patterned features are typically spaced approximately 1-200 μm apart and are preferably 2-10 μm apart. It will be appreciated, however, that any suitable height, width and spacing that facilitates lateral epitaxial overgrowth of a material may be used.

Accommodating buffer layer 176 is epitaxially deposited between patterned features 174 and overlying substrate 172. Accommodating buffer layer 176 may be formed of any of those materials described above for accommodating buffer layer 144 of FIG. 24 and accommodating buffer layer 162 of FIG. 25 and may be formed by the process described above for accommodating buffer layer 24 of FIGS. 1 and 2. Because the dielectric material that forms patterned features 174 does not provide for the nucleation of the material that forms accommodating buffer layer 176, accommodating buffer layer 176 does not epitaxially grow on patterned features 174. In accordance with one embodiment of the invention, structure 170 also includes a discontinuous amorphous interface layer 180 positioned between substrate 172 and monocrystalline accommodating buffer layer 176. Amorphous interface layer 180 may be formed of a silicon oxide such as that comprising layer 148 of FIGS. 24 and 25.

Structure 170 may also include a discontinuous template layer 182 formed between accommodating buffer layer 176 and monocrystalline material layer 178. Template layer 182 may be formed of any of the materials that comprise template layer 30 of FIGS. 1-3, template layer 60 of FIG. 12, capping layer 82 of FIG. 20 and template layer 130 of FIG. 23.

Monocrystalline material layer 178 is grown by LEO processing overlying accommodating buffer layer 172 and between patterned features 174. The monocrystalline material of layer 178 grows vertically to fill the space between patterned features 174 and then grows laterally over patterned features 174. With this growth process, defect density is reduced, as the lateral propagation of dislocations present at the accommodating buffer layer/monocrystalline material layer interface due to lattice mismatch are limited. Accordingly, the vertical propagation of the defects within the monocrystalline material layer is limited, thereby creating a high-quality, relatively defect-free monocrystalline material layer 178. Monocrystalline material layer 178 may be formed of any of the materials described above for monocrystalline material layer 146 with reference to FIG. 24 and monocrystalline material layer 164 with reference to FIG. 25.

FIG. 27 illustrates, in cross section, a portion of a semiconductor structure 190 in accordance with a further embodiment of the invention. Structure 190 comprises a silicon substrate 172 with patterned features 174, as described above with reference to FIG. 26. Structure 190 further comprises an accommodating buffer layer 192. Accommodating buffer layer 192 may be formed of the same materials as set forth above for accommodating buffer layer 176 illustrated in FIG. 26. Accommodating buffer layer 192 is epitaxially grown overlying substrate 172 via LEO between patterned features 174. Accommodating buffer layer 192 grows vertically to fill the space between patterned features 174 and then grows laterally over patterned features 174. Using LEO, a high quality monocrystalline accommodating buffer layer may be formed overlying substrate 172. In accordance with one embodiment of the invention, structure 190 also includes discontinuous amorphous interface layer 180 positioned between substrate 172 and monocrystalline accommodating buffer layer 192. A monocrystalline material layer 194 is epitaxially grown overlying accommodating buffer layer 192. Structure 190 may also include a template layer 196 between accommodating buffer layer 192 and monocrystalline material layer 194. Template layer 196 may be formed of any of the materials that comprise discontinuous template layer 182 of FIG. 26.

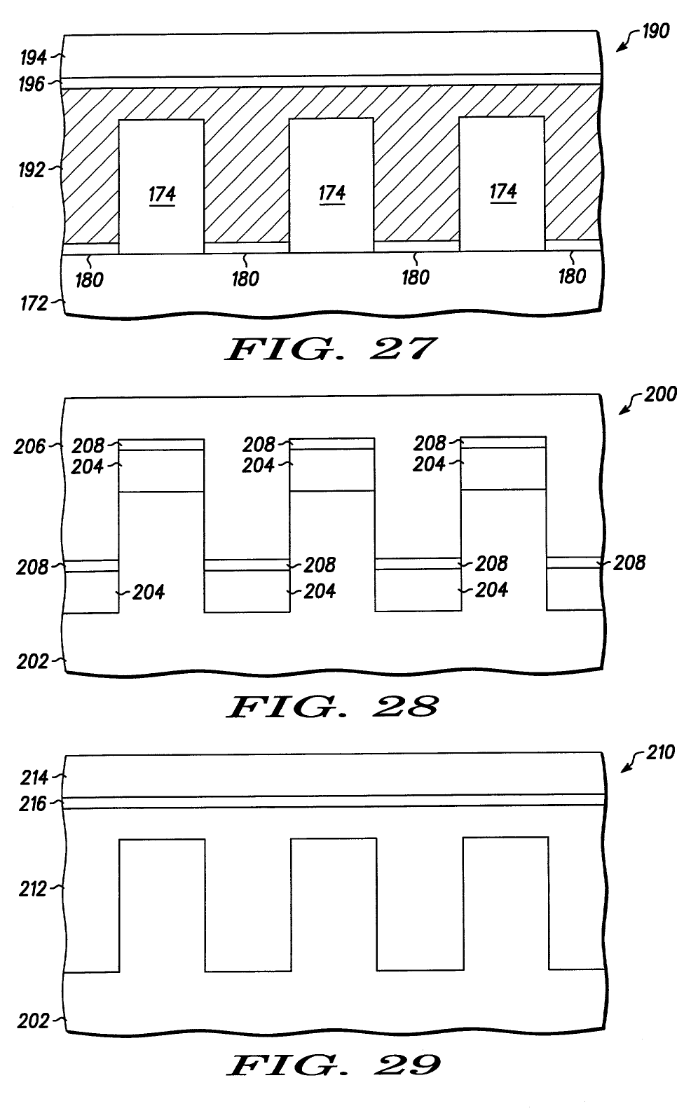

In another exemplary embodiment of the invention, the accommodating buffer layer and amorphous interface layer of structures 140, 160, 170 and 190 may be subject to an anneal process to form an amorphous layer, similar to amorphous layer 36 as described above with reference to FIG. 3. FIG. 28 illustrates, in cross section, a portion of a semiconductor structure 200 that is similar to structure 140 of FIG. 24, except that structure 200 includes an amorphous layer 204, rather than accommodating buffer layer 144 and amorphous interface layer 148.

Amorphous layer 204 may be formed by first forming an accommodating buffer layer and an amorphous interface layer in a similar manner to that described above with respect to structure 140. In one exemplary embodiment, a template layer 208 may be formed overlying the accommodating buffer layer. A seed layer (not shown) of a monocrystalline material layer is then formed by epitaxial growth overlying the monocrystalline accommodating buffer layer. The accommodating buffer layer is subsequently exposed to an anneal process to convert the monocrystalline accommodating buffer layer to an amorphous layer 204. Additional monocrystalline material then may be further epitaxially grown on the seed layer to form monocrystalline material layer 206 having a desired thickness. Alternatively, monocrystalline material layer 206 may be epitaxially grown to a desired thickness before the anneal process. Amorphous layer 204 formed in this manner comprises materials from both the accommodating buffer and interface layers, which amorphous layers may or may not amalgamate. Thus, layer 204 may comprise one or two amorphous layers. Formation of amorphous layer 204 between substrate 202 and monocrystalline material layer 206 relieves stresses between layers 202 and 204.

In a similar manner, a structure similar to FIG. 26 may be formed, except that the structure may include an amorphous layer, formed using the anneal process described above, rather than accommodating buffer layer 176 and amorphous interface layer 180.

FIG. 29 schematically illustrates, in cross section, a portion of a semiconductor structure 210 in accordance with another exemplary embodiment of the invention. Structure 210 is similar to structure 160 shown in FIG. 25, except that structure 210 includes an amorphous layer 212, rather than accommodating buffer layer 162 and amorphous interface layer 148. Amorphous layer 212 is formed by first growing by LEO processing an accommodating buffer layer and an amorphous interface layer in a similar manner to that described above to grow accommodating buffer layer 162 and amorphous interface layer 148. In one exemplary embodiment, a template layer 216 is formed overlying the accommodating buffer layer. A seed layer (not shown) of a monocrystalline material layer is epitaxially grown overlying template layer 216. The accommodating buffer layer is then exposed to an anneal process to convert the monocrystalline accommodating buffer layer to an amorphous layer 212. Additional monocrystalline material then may be further epitaxially grown on the seed layer to form monocrystalline material layer 214 having a desired thickness. Alternatively, monocrystalline material layer 214 may be epitaxially grown to a desired thickness before the anneal process.

In a similar manner, a structure similar to FIG. 27 may be formed, except that the structure may include an amorphous layer, formed using the anneal process described above, rather than accommodating buffer layer 192 and amorphous interface layer 180.

The following non-limiting, illustrative examples illustrate various combinations of materials useful in structures 140, 160, 170 and 190 in accordance with various alternative embodiments of the invention. These examples are merely illustrative, and it is not intended that the invention be limited to these illustrative examples.

### EXAMPLE 7

This embodiment of the invention is an example of structure 140 illustrated in FIG. 24. Monocrystalline substrate 142 is a silicon substrate oriented in the (100) direction. The silicon substrate can be, for example, a silicon substrate as is commonly used in making CMOS integrated circuits having a diameter of about 200-300 mm. A plurality of patterned features 152 having a generally circular cross-sectional shape have been formed in the top surface of the silicon substrate by RIE. In accordance with this embodiment of the invention, a discontinuous accommodating buffer layer 144 is a monocrystalline layer of Sr_{z}Ba_{1-z}TiO₃, where z ranges from 0 to 1, and the amorphous interface layer is a layer of silicon oxide (SiOₓ) formed at the interface between the silicon substrate and the accommodating buffer layer. The value of z is selected to obtain one or more lattice constants closely matched to corresponding lattice constant of the subsequently formed layer 146. The accommodating buffer layer can have a thickness of about 2 to about 100 nm and preferably has a thickness of about 3-5 nm. The amorphous interface layer of silicon oxide can have a thickness of about 0.5-5 nm, and preferably a thickness of about 1 to 2 nm.

In accordance with this embodiment of the invention, monocrystalline material layer 146 is a compound semiconductor of GaAs. The thickness of layer 146 generally depends on the application for which the layer is being prepared. To facilitate the epitaxial growth of the GaAs on the monocrystalline accommodating buffer layer, a template layer is formed by capping the accommodating buffer layer. The template layer is preferably 1-10 monolayers of Ti, Ga, Ti—O—Ga, Ti—As, Ti—O—As, Sr—O—As, Sr—Ga—O, or Sr—Al—O. By way of a preferred example, 1-2 monolayers of Ti—O—As or Ti—Ga—O have been illustrated to successfully grow GaAs layers.

### EXAMPLE 8

This embodiment of the invention is an example of structure 160 illustrated in FIG. 25. Monocrystalline substrate 142 with patterned features 152 and amorphous interface layer 148 may be the same as described above in Example 7. In this embodiment of the invention, accommodating buffer layer 162 is a monocrystalline oxide formed of BaZrO₃. The lattice structure of the resulting crystalline oxide exhibits a 45 degree rotation with respect to the substrate silicon lattice structure. Accommodating buffer layer 162 is epitaxially grown via LEO processing between and over patterned features 152 to any thickness suitable for a desired application. When grown to its desired thickness, accommodating buffer layer 162 may be terminated with 1-2 monolayers of zirconium followed by deposition of 1-2 monolayers of arsenic to form a Zr—As template. A monocrystalline layer of the compound semiconductor material from the indium phosphide (InP) system is then grown on the template layer. For example, the compound semiconductor material can be, for example, InP, InGaAs, AlInAs or AlGaAsP. A suitable template for this structure may be 1-10 monolayers of Zr—As.

### EXAMPLE 9

This embodiment of the invention is an example of structure 170 illustrated in FIG. 26. The substrate is preferably a silicon wafer as described above. Patterned features 174 of Si₃N₄ are subsequently lithographically deposited on the silicon substrate to form a pattern suitable for a subsequent lateral epitaxial overgrowth of monocrystalline material. A suitable accommodating buffer layer material is SrₓBa₁₋ₓTiO₃, where x ranges from 0 to 1, having a thickness of about 2-100 nm and preferably a thickness of about 5-15 nm. Monocrystalline material layer 178 may be an epitaxial film comprising a II-VI material such as ZnSe or ZnSSe. A suitable template for this material system includes 1-10 monolayers of zinc-oxygen (Zn—O), followed by 1-2 monolayers of an excess of zinc followed by the selenidation of zinc on the surface. Alternatively, a template can be, for example, 1-10 monolayers of strontium-sulfur (Sr—S) followed by the ZnSe or ZnSSe. ZnSe or ZnSSe is then epitaxially deposited via LEO processing between the patterned features and then over the features.

### EXAMPLE 10

This embodiment of the invention is an example of structure 190 illustrated in FIG. 27. The substrate is preferably a silicon wafer as described above. Patterned features 174 of SiO₂ are subsequently lithographically deposited on the silicon substrate to form a pattern suitable for a subsequent lateral epitaxial overgrowth of monocrystalline material. Accommodating buffer layer 192 is formed of SrHfO₃ and is epitaxially grown between and over patterned features 174 to any thickness suitable for a desired application. The surface of the accommodating buffer layer is then terminated with 1-2 monolayers of hafnium followed by deposition of 1-2 monolayers of arsenic to form a Hf—As template layer 196. A monocrystalline material layer 194 of InP is then epitaxially deposited over the template layer.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate having a plurality of patterned features;
a monocrystalline accommodating buffer layer deposited discontinuously between and on said plurality of features; and
a monocrystalline material layer overlying said monocrystalline accommodating buffer layer.

2. The semiconductor structure of claim 1, said monocrystalline substrate comprising silicon.

3. The semiconductor structure of claim 1, wherein said monocrystalline material layer comprises at least one of a semiconductor material, a compound semiconductor, a metal and a non-metal.

4. The semiconductor structure of claim 1, wherein said monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

5. The semiconductor structure of claim 1, wherein said monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

6. The semiconductor structure of claim 1, wherein said accommodating buffer layer comprises a material selected from at least one of: alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

7. The semiconductor structure of claim 1, wherein said monocrystalline accommodating buffer layer has a thickness in the range of about 2-100 nm.

8. The semiconductor structure of claim 1, further comprising an amorphous oxide interface layer underlying said monocrystalline accommodating buffer layer.

9. The semiconductor structure of claim 1, further comprising a template layer formed discontinuously overlying said accommodating buffer layer.

10. The semiconductor structure of claim 9, said template layer comprising a Zint1-type phase material.

11. The semiconductor structure of claim 10, said Zint1-type phase material comprising at least one of SrAl₂, (MgCaYb)Ga₂, (Ca,Sr,Eu,Yb)In₂, BaGe₂As, and SrSn₂As₂.

12. The semiconductor structure of claim 9, said template layer comprising a surfactant material.

13. The semiconductor structure of claim 12, said surfactant material comprising at least one of Al, Bi, In, and Ga.

14. The semiconductor structure of claim 12, said template layer further comprising a capping layer.

15. The semiconductor structure of claim 14, said capping layer formed by exposing said surfactant material to a cap-inducing material.

16. The semiconductor structure of claim 15, said cap-inducing material comprising at least one of As, P, Sb, and N.

17. The semiconductor structure of claim 9, said template layer comprising a capping layer formed of about 1-10 monolayers of one of a material M-N and a material M-O—N, wherein M is selected from at least one of Zr, Hf, Ti, Sr, and Ba and N is selected from at least one of As, P, Ga, Al, and In.

18. The semiconductor structure of claim 1, wherein said substrate is characterized by a first lattice constant and said monocrystalline material layer is characterized by a second lattice constant different than said first lattice constant.

19. The semiconductor structure of claim 1, wherein said plurality of patterned features are formed by a process selected from one of reactive ion etching, chemical etching, sputtering and machining.

20. The semiconductor structure of claim 1, wherein said accommodating buffer layer is formed of a monocrystalline oxide material and is subsequently heat treated to convert said monocrystalline oxide material to an amorphous oxide.

21. A semiconductor structure comprising:
a monocrystalline substrate comprising a plurality of patterned features;
a monocrystalline accommodating buffer layer grown via lateral epitaxial overgrowth processing between and over said patterned features; and
a monocrystalline material layer overlying said monocrystalline accommodating buffer layer.

22. The semiconductor structure of claim 21, said monocrystalline substrate comprising silicon.

23. The semiconductor structure of claim 21, wherein said monocrystalline material layer comprises at least one of a semiconductor material, a compound semiconductor, a metal and a non-metal.

24. The semiconductor structure of claim 21, wherein said monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

25. The semiconductor structure of claim 21, wherein said monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

26. The semiconductor structure of claim 21, wherein said accommodating buffer layer comprises a material selected from at least one of: alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

27. The semiconductor structure of claim 21, further comprising an amorphous oxide interface layer underlying said monocrystalline accommodating buffer layer.

28. The semiconductor structure of claim 21, further comprising a template layer formed overlying said accommodating buffer layer.

29. The semiconductor structure of claim 28, said template layer comprising a Zint1-type phase material.

30. The semiconductor structure of claim 29, said Zint1-type phase material comprising at least one of SrAl₂, (MgCaYb)Ga₂, (Ca,Sr,Eu,Yb)In₂, BaGe₂As, and SrSn₂As₂.

31. The semiconductor structure of claim 28, said template layer comprising a surfactant material.

32. The semiconductor structure of claim 31, said surfactant material comprising at least one of Al, Bi, In, and Ga.

33. The semiconductor structure of claim 31, said template layer further comprising a capping layer.

34. The semiconductor structure of claim 33, said capping layer formed by exposing said surfactant material to a cap-inducing material.

35. The semiconductor structure of claim 34, said cap-inducing material comprising at least one of As, P, Sb, and N.

36. The semiconductor structure of claim 28, said template layer comprising a capping layer formed of about 1-10 monolayers of one of a material M-N and a material M-O—N, wherein M is selected from at least one of Zr, Hf, Ti, Sr, and Ba and N is selected from at least one of As, P, Ga, Al, and In.

37. The semiconductor structure of claim 21, wherein said substrate is characterized by a first lattice constant and said monocrystalline material layer is characterized by a second lattice constant different than said first lattice constant.

38. The semiconductor structure of claim 21, wherein said plurality of patterned features are formed by a process selected from one of reactive ion etching, chemical etching, sputtering and machining.

39. The semiconductor structure of claim 21, wherein said accommodating buffer layer is formed of a monocrystalline oxide material and is subsequently heat treated to convert said monocrystalline oxide material to an amorphous oxide.

40. A semiconductor structure comprising:
a monocrystalline substrate;
a plurality of patterned features formed overlying said monocrystalline substrate;
a monocrystalline accommodating buffer layer deposited discontinuously between said plurality of features; and
a monocrystalline material layer overlying said monocrystalline accommodating buffer layer.

41. The semiconductor structure of claim 40, said monocrystalline substrate comprising silicon.

42. The semiconductor structure of claim 40, said patterned features being formed of a dielectric material.

43. The semiconductor structure of claim 42, said dielectric material comprising at least one of SiO₂ and SiNₓ, where x is greater than 0.

44. The semiconductor structure of claim 40, said plurality of patterned features being lithographically deposited.

45. The semiconductor structure of claim 40, wherein said monocrystalline material layer comprises at least one of a semiconductor material, a compound semiconductor, a metal and a non-metal.

46. The semiconductor structure of claim 40, wherein said monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

47. The semiconductor structure of claim 40, wherein said monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

48. The semiconductor structure of claim 40, wherein said accommodating buffer layer comprises a material selected from at least one of: alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

49. The semiconductor structure of claim 40, wherein said monocrystalline accommodating buffer layer has a thickness in the range of about 2-100 nm.

50. The semiconductor structure of claim 40, further comprising an amorphous oxide interface layer underlying said monocrystalline accommodating buffer layer.

51. The semiconductor structure of claim 40, further comprising a template layer formed discontinuously overlying said accommodating buffer layer.

52. The semiconductor structure of claim 51, said template layer comprising a Zint1-type phase material.

53. The semiconductor structure of claim 52, said Zint1-type phase material comprising at least one of SrAl₂, (MgCaYb)Ga₂, (Ca,Sr,Eu,Yb)In₂, BaGe₂As, and SrSn₂As₂.

54. The semiconductor structure of claim 51, said template layer comprising a surfactant material.

55. The semiconductor structure of claim 54, said surfactant material comprising at least one of Al, Bi, In, and Ga.

56. The semiconductor structure of claim 54, said template layer further comprising a capping layer.

57. The semiconductor structure of claim 56, said capping layer formed by exposing said surfactant material to a cap-inducing material.

58. The semiconductor structure of claim 57, said cap-inducing material comprising at least one of As, P, Sb, and N.

59. The semiconductor structure of claim 51, said template layer comprising a capping layer formed of about 1-10 monolayers of one of a material M-N and a material M-O—N, wherein M is selected from at least one of Zr, Hf, Ti, Sr, and Ba and N is selected from at least one of As, P, Ga, Al, and In.

60. The semiconductor structure of claim 40, wherein said substrate is characterized by a first lattice constant and said monocrystalline material layer is characterized by a second lattice constant different than said first lattice constant.

61. The semiconductor structure of claim 40, wherein said accommodating buffer layer is formed of a monocrystalline oxide material and is subsequently heat treated to convert said monocrystalline oxide material to an amorphous oxide.

62. A semiconductor structure comprising:
a mono crystalline substrate;
a plurality of patterned features formed overlying said monocrystalline substrate;
a monocrystalline accommodating buffer layer grown via lateral epitaxial overgrowth processing between and over said patterned features; and
a monocrystalline material layer overlying said monocrystalline accommodating buffer layer.

63. The semiconductor structure of claim 62, said monocrystalline substrate comprising silicon.

64. The semiconductor structure of claim 62, said patterned features being formed of a dielectric material.

65. The semiconductor structure of claim 64, said dielectric material comprising at least one of SiO₂ and SiNₓ, where x is greater than 0.

66. The semiconductor structure of claim 62, said plurality of patterned features being lithographically deposited.

67. The semiconductor structure of claim 62, wherein said monocrystalline material layer comprises at least one of a semiconductor material, a compound semiconductor, a metal and a non-metal.

68. The semiconductor structure of claim 62, wherein said monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

69. The semiconductor structure of claim 62, wherein said monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

70. The semiconductor structure of claim 62, wherein said accommodating buffer layer comprises a material selected from at least one of: alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

71. The semiconductor structure of claim 62, further comprising an amorphous oxide interface layer underlying said monocrystalline accommodating buffer layer.

72. The semiconductor structure of claim 62, further comprising a template layer formed overlying said accommodating buffer layer.

73. The semiconductor structure of claim 72, said template layer comprising a Zint1-type phase material.

74. The semiconductor structure of claim 73, said Zint1-type phase material comprising at least one of SrAl₂, (MgCaYb)Ga₂, (Ca,Sr,Eu,Yb)In₂, BaGe₂As, and SrSn₂As₂.

75. The semiconductor structure of claim 72, said template layer comprising a surfactant material.

76. The semiconductor structure of claim 75, said surfactant material comprising at least one of Al, Bi, In, and Ga.

77. The semiconductor structure of claim 75, said template layer further comprising a capping layer.

78. The semiconductor structure of claim 77, said capping layer formed by exposing said surfactant material to a cap-inducing material.

79. The semiconductor structure of claim 78, said cap-inducing material comprising at least one of As, P, Sb, and N.

80. The semiconductor structure of claim 72, said template layer comprising a capping layer formed of about 1-10 monolayers of one of a material M-N and a material M-O—N, wherein M is selected from at least one of Zr, Hf, Ti, Sr, and Ba and N is selected from at least one of As, P, Ga, Al, and In.

81. The semiconductor structure of claim 62, wherein said substrate is characterized by a first lattice constant and said monocrystalline material layer is characterized by a second lattice constant different than said first lattice constant.

82. The semiconductor structure of claim 62, wherein said accommodating buffer layer is formed of a monocrystalline oxide material and is subsequently heat treated to convert said monocrystalline oxide material to an amorphous oxide.

83. A process for fabricating a semiconductor structure comprising:
providing a monocrystalline substrate;
forming a plurality of patterned features on a surface of said monocrystalline substrate;
depositing an accommodating buffer layer between said patterned features; and
depositing a monocrystalline material layer overlying said accommodating buffer layer and said patterned features.

84. The process of claim 83, wherein said forming a plurality of patterned features comprising forming by a process selected from one of reactive ion etching, chemical etching, sputtering and machining.

85. The process of claim 83, wherein said forming a plurality of patterned features comprises lithographically depositing said plurality of patterned features on said surface of said monocrystalline substrate.

86. The process of claim 85, said plurality of patterned features being formed of at least one of SiO₂ and SiNₓ, where x is greater than 0.

87. The process of claim 83, further comprising forming an amorphous interface layer between said substrate and said accommodating buffer layer.

88. The process of claim 83, wherein said monocrystalline substrate comprises silicon.

89. The process of claim 83, wherein said monocrystalline material layer comprises at least one of a semiconductor material, a compound semiconductor, a metal and a non-metal.

90. The process of claim 83, wherein said monocrystalline material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

91. The process of claim 83, wherein said monocrystalline material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

92. The process of claim 83, wherein said accommodating buffer layer comprises a material selected from at least one of: alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

93. The process of claim 83, further comprising forming a template layer overlying said accommodating buffer layer.

94. The process of claim 93 said template layer comprising a Zint1-type phase material.

95. The process of claim 94, said Zint1-type phase material comprising at least one of SrAl₂, (MgCaYb)Ga₂, (Ca,Sr,Eu,Yb)In₂, BaGe₂As, and SrSn₂As₂.

96. The process of claim 93, said template layer comprising a surfactant material.

97. The process of claim 96, said surfactant material comprising at least one of Al, Bi, In, and Ga.

98. The process of claim 96, said template layer further comprising a capping layer.

99. The process of claim 98, said capping layer formed by exposing said surfactant material to a cap-inducing material.

100. The process of claim 99, said cap-inducing material comprising at least one of As, P, Sb, and N.

101. The process of claim 83, said template layer comprising a capping layer formed of about 1-10 monolayers of one of a material M-N and a material M-O—N, wherein M is selected from at least one of Zr, Hf, Ti, Sr, and Ba and N is selected from at least one of As, P, Ga, Al, and In.

102. The process of claim 83, wherein each of said depositing comprises depositing by a process selected from one of MBE, MOCVD, MEE, CVD, PVD, PLD, CSD, and ALE.

103. The process of claim 83, wherein said depositing an accommodating buffer layer comprises depositing an accommodating buffer layer to a thickness in the range of about 2-100 nm.

104. The process of claim 83, wherein said accommodating buffer layer is formed of a monocrystalline oxide material and said process further comprises heat treating said monocrystalline oxide material to an amorphous oxide material.
